(19) United States
(12) Patent Application Publication
(10) Pub. No.: US 2015/0342046 A1
(43) Pub. Date: Nov. 26, 2015

(54) PRINTED CIRCUIT BOARD, METHOD FOR MAUFACTURING THE SAME AND PACKAGE ON PACKAGE HAVING THE SAME

(71) Applicant: SAMSUNG ELECTRO-MECHANICS CO., LTD., Suwon-Si (KR)

(72) Inventors: Hye Jin KIM, Suwon-Si (KR); Hye Won JUNG, Suwon-Si (KR); Myung Sam KANG, Suwon-Si (KR); Kang Wook BONG, Suwon-Si (KR); Young Gwan KO, Suwon-Si (KR); Min Jae SEONG, Suwon-Si (KR)

(21) Appl. No.: 14/719,309

(22) Filed: May 21, 2015

(30) Foreign Application Priority Data
May 23, 2014 (KR) 10-2014-0062530
Dec. 5, 2014 (KR) 10-2014-0174195
Dec. 30, 2014 (KR) 10-2014-0194133

(51) Int. Cl. H05K 1/11; C25D 5/02; H05K 3/06; H05K 3/00; H05K 1/18; H05K 1/02

(52) U.S. Cl. CPC H05K 1/111; H05K 1/115; H05K 1/183; H05K 1/185; H05K 1/0298; H05K 3/064; H05K 3/0091; C25D 5/02; H05K 2201/10734; H05K 2201/10674

(57) ABSTRACT

A printed circuit board connected to one surface of a substrate and a first electronic component is mounted on the one surface. The printed circuit board includes at least one insulating layer and the insulating layer has a cavity accommodating at least a portion of the first electronic component formed therein, and the cavity has an internal surface made of an insulating material.

### CROSS-REFERENCE TO RELATED APPLICATION

This application claims the benefit of priority to Korean Patent Application No. 10-2014-0194133, filed on Dec. 30, 2014, entitled “Printed Circuit Board, Method for Manufacturing the Same and Package on Package having the thereof”, Korean Patent Application No. 10-2014-0062530, filed on May 23, 2014, entitled “Package Board, Method for Manufacturing the Same and Package on Package Having the thereof”, and Korean Patent Application No. 10-2014-0174195, filed on Dec. 5, 2014, entitled “Package Board, Method for Manufacturing the Same and Package on Package Having the thereof” which are hereby incorporated by reference in its entirety into this application.

### TECHNICAL FILED

The present disclosure relates to a printed circuit board, a method for manufacturing the same, and a package on package having the same.

### BACKGROUND

An electronic technology has recently adopted a mounting technology using a multi-layer printed circuit board capable of realizing high densification and high integration upon mounting components in order to achieve miniaturization and thinness of an electronic device. The multi-layer printed circuit board has employed elements such as a microcircuit, a bump, and the like in order to implement high densification and high integration. In recent times, a semiconductor package such as a system in package (SIP), a chip sized package (CSP), a flip chip package (FCP), configured as a package by mounting an electronic component on a printed circuit board in advance has been actively developed. In addition, a need exists for a package on package (POP) in which a controlling device and a memory device are implemented in a single package form to thereby miniaturize a high performance smart phone and improve performance thereof.

### SUMMARY

An aspect of the present disclosure may provide a printed circuit board capable of easily decreasing an occurrence of a bridge of an external connection terminal and implementing a fine pitch, a method for manufacturing the same, and a package on package having the same.

An aspect of the present disclosure may also provide a printed circuit board capable of decreasing an overall thickness of a package on package, a method for manufacturing the same, and the package on package having the same.

According to an aspect of the present disclosure, a printed circuit board connected to one surface of a substrate having a first electronic component mounted on the one surface and including at least one insulating layer may be provided, wherein the at least one insulating layer has a cavity accommodating at least a portion of the first electronic component formed therein, and the cavity has an internal surface made of an insulating material.

The cavity may have a concave shapeformed in a lower surface of the insulating layer.

The printed circuit board may further include a connection pad formed in the insulating layer and the connection pad is spaced apart from the cavity.

The connection pad may have a thickness equal to or smaller than the insulating layer.

The cavity may have an entire internal surface made of the same material as the insulating layer.

According to another aspect of the present disclosure, a method for a printed circuit board may include forming a cavity pattern on a carrier substrate; forming an insulating layer formed on the carrier substrate to bury the cavity pattern; removing the carrier substrate; and removing the cavity pattern to form a cavity.

In the forming of the cavity pattern, when the cavity pattern is formed, a connection pad may be further formed on the carrier substrate.

According to another aspect of the present disclosure, a package on package may include: a lower package including a lower package substrate and a first electronic component disposed on the lower package substrate; an upper package substrate including at least one insulating layer, the insulating layer having a cavity accommodating at least a portion of the first electronic component formed therein, and the cavity having an internal surface made of an insulating material; and an external connection terminal formed between the lower package substrate and the upper package substrate and electrically connecting the upper package substrate and the lower package substrate, wherein the cavity accommodates at least a portion of the first electronic component.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is an illustrative diagram illustrating a printed circuit board according to an exemplary embodiment of the present disclosure;

FIGS. 2 through 16 are diagrams illustrating a method for manufacturing a printed circuit board according to an exemplary embodiment of the present disclosure; and

FIG. 17 is an illustrative diagram illustrating a package on package according to an exemplary embodiment of the present disclosure.

### DETAILED DESCRIPTION

The objects, features and advantages of the present disclosure will be more clearly understood from the following detailed description of the exemplary embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present disclosure, when it is determined that the detailed description of the related art would obscure the gist of the present disclosure, the description thereof will be omitted.

Hereinafter, exemplary embodiments of the present disclosure will be described in detail with reference to the accompanying drawings.

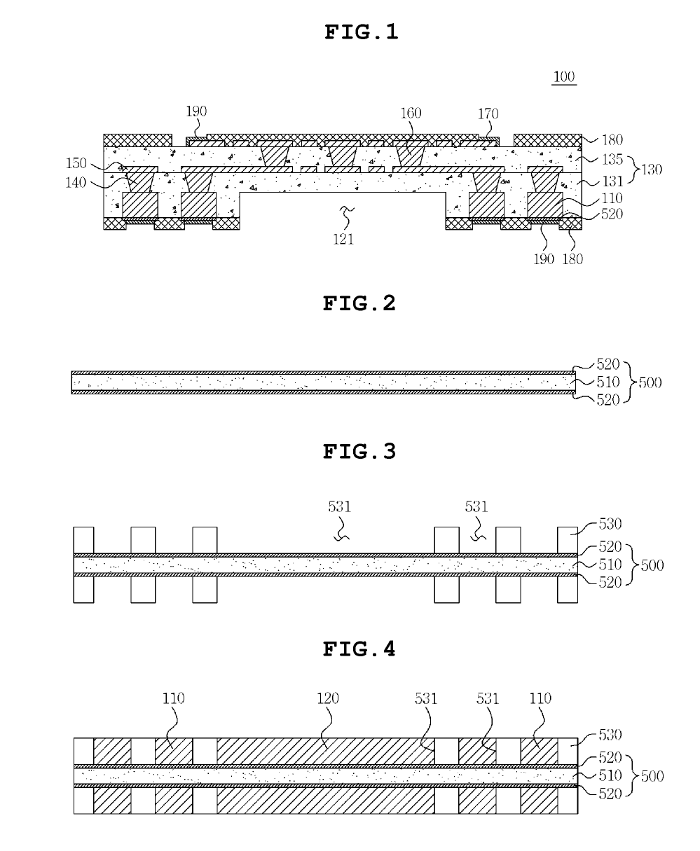

FIG. 1 is an illustrative diagram illustrating a printed circuit board according to an exemplary embodiment of the present disclosure.

Although not illustrated, a printed circuit board 100 according to an exemplary embodiment of the present disclosure is connected to one surface of a substrate having one surface on which an electronic component is mounted. The above-mentioned printed circuit board 100 includes at least one insulating layer 130. The insulating layer 130 includes a cavity 121 accommodating at least a portion of the electronic component (not illustrated), and an inner surface of the cavity 121 is made of an insulating material.

Referring to FIG. 1, the printed circuit board 100 according to an exemplary embodiment of the present disclosure includes the insulating layer 130, a connection pad 110, an inner layer circuit pattern 150, an outer layer circuit pattern 170, a first via 140, a second via 160, and a protection layer 180.

According to an exemplary embodiment of the present disclosure, the insulating layer 130 may be made of a complex polymer resin which is typically used as an interlayer insulating material. For example, the insulating layer 130 may be made of a prepreg, Ajinomoto Build up Film (ABF), and an epoxy based resin such as FR-4, BismaleimideTriazine (BT), or the like. However, in an exemplary embodiment of the present disclosure, the material of forming the insulating layer 130 is not limited thereto. The material of forming the insulating layer 130 according to an exemplary embodiment of the present disclosure may be selected from insulating materials known in the field of circuit board.

According to an exemplary embodiment of the present disclosure, the insulating layer 130 is classified into a first insulating layer 131 and a second insulating layer 135. The second insulating layer 135 is formed on the first insulating layer 131.

FIG. 1 illustrates a case in which the first insulating layer 131 and the second insulating layer 135 are made of the same material. However, the exemplary embodiment of the present disclosure is not limited to the case in which the first insulating layer 131 and the second insulating layer 135 are made of the same material. For example, the first insulating layer 131 may be made of an insulating material including glass fiber, and the second insulating layer 135 may be made of an insulating material which does not include the glass fiber. As such, the materials of forming the first insulating layer 131 and the second insulating layer 135 may be changed according to a selection of those skilled in the art.

According to an exemplary embodiment of the present disclosure, the first insulating layer 131 is provided with a cavity 121, which is a groove having a predetermined depth from a lower surface of the first insulating layer 131 to an inner portion thereof. That is, according to an exemplary embodiment of the present disclosure, the cavity 121 is formed in the lower portion of the first insulating layer 131 in a concave form. When a package on package is formed, at least a portion of an electronic component (not shown) of a lower package is accommodated in the cavity 121 according to an exemplary embodiment of the present disclosure. Therefore, the cavity 121 according to an exemplary embodiment of the present disclosure has a size to accommodate at least a portion of the electronic component therein later. Here, although not shown, the cavity 121 accommodates the electronic component in a state in which the cavity 121 is spaced apart from the electronic component by a predetermined interval. In addition, according to an exemplary embodiment of the present disclosure, the cavity 121 is formed in the first insulating layer 131, and an entire internal surface of the cavity 121 is made of an insulating material. That is, it may be said that the internal surface of the cavity 121 is made of the first insulating layer 131.

In addition, according to an exemplary embodiment of the present disclosure, as shown in FIG. 1, the cavity 121 has a depth smaller than a thickness of the first insulating layer 131.

According to an exemplary embodiment of the present disclosure, the connection pad 110 is buried in the first insulating layer 131. Although FIG. 1 shows a case in which the connection pads 110 are formed at left and right of the cavity 121, the connection pad 110 may surround a side edge of the cavity 121.

According to an exemplary embodiment of the present disclosure, the connection pad 110 has a thickness equal to or thinner than that of the first insulating layer 131. Here, the connection pad 110 according to an exemplary embodiment of the present disclosure has the thickness corresponding to the depth of the cavity 121. For example, as shown in FIG. 1, the connection pad 110 has the same thickness as the depth of the cavity 121. Here, the term “the same” means a term “substantially same” That is, the term “the same” means a term “the same” considering error or deviation occurring during a manufacturing process.

According to an exemplary embodiment of the present disclosure, as shown in FIG. 1, the connection pad 110 has the thickness thicker than that of other circuit patterns.

The connection pad 110 according to an exemplary embodiment of the present disclosure may have a metal layer formed therebelow. The metal layer 520 is formed below the connection pad 110 and has a structure protruding from the first insulating layer 131.

The connection pad 110 and the metal layer 520 according to an exemplary embodiment of the present disclosure are made of copper (Cu). However, the material of the connection pad 110 and the metal layer 520 is not limited to the copper and any material may be used as long as it is a conductive materials used in the field of circuit board.

According to an exemplary embodiment of the present disclosure, the inner layer circuit pattern 150 is formed in the insulating layer 130. For example, the inner layer circuit pattern 150 may be formed on the first insulating layer 131 and be buried in the second insulating layer 135. Although an exemplary embodiment of the present disclosure shows and describes the case in which the inner layer circuit layer 150 is formed in a single layer, the present disclosure is not limited thereto. That is, the inner layer circuit pattern 150 according to an exemplary embodiment of the present disclosure may be formed in a multi-layer of two layers or more according to a selection of those skilled in the art.

According to an exemplary embodiment of the present disclosure, the outer layer circuit pattern 170 is formed on the second insulating layer 135.

The inner layer circuit pattern 150 and the outer layer circuit pattern 170 according to an exemplary embodiment of the present disclosure may be made of copper (Cu). However, the material of the inner layer circuit pattern 150 and the outer layer circuit pattern 170 is not limited to the copper and any material may be used as long as it is a conductive materials used in the field of circuit board.

According to an exemplary embodiment of the present disclosure, the first via 140 is formed in the first insulating layer 131. According to an exemplary embodiment of the present disclosure, a lower surface of the first via 140 is bonded to the connection pad 110 and an upper surface thereof is bonded to the inner layer circuit pattern 150. The first via 140 electrically connects the connection pad 110 and the inner layer circuit pattern 150 to each other.

According to an exemplary embodiment of the present disclosure, the outer layer circuit pattern 170 may include a mounting pattern which is electrically connected to an external component, when the external component is mounted on the insulating layer 130. For example, the mounting pattern is a portion shown in FIG. 1 so that at least a portion thereof is exposed to the outside by the protection layer 180 out of the outer layer circuit pattern 170.

According to an exemplary embodiment of the present disclosure, the via 140 has a diameter of the upper surface larger than a diameter of the lower surface.

According to an exemplary embodiment of the present disclosure, an external configuration unit positioned outside the printed circuit board 100 and the inner layer circuit pattern 150 are electrically connected by the connection pad 110, the first via 140, and the metal layer 520. Here, the external configuration unit may be the electronic component, the printed circuit board, a main board substrate, the package, and the like, for example.

In addition, when the printed circuit board 100 according to an exemplary embodiment of the present disclosure is stacked on a lower printed circuit board (not shown), a portion of the electronic component mounted on the lower package is accommodated in the cavity 121. Therefore, an interval between the printed circuit board 100 and the lower printed circuit board is decreased as much as a height of the electronic component accommodated in the cavity 121. Therefore, an amount of solder (see a second external connection terminal 340 shown in FIG. 17) for a connection with the lower printed circuit board may be reduced as much as the decreased interval. Therefore, since an occurrence rate of a bride between the solders is also decreased, assembly yield may be increased and a fine pitch of the connection pad 110 may be implemented.

The second via 160 according to an exemplary embodiment of the present disclosure is formed in the second insulating layer 135. According to an exemplary embodiment of the present disclosure, a lower surface of the second via 160 is bonded to the inner layer circuit pattern 150 and an upper surface thereof is bonded to the outer layer circuit pattern 170. The second via 160 electrically connects the inner layer circuit pattern 150 and the outer layer circuit pattern 170.

According to an exemplary embodiment of the present disclosure, the protection layer 180 is formed on the second insulating layer 135 and the outer layer circuit pattern 170. The protection layer 180 according to an exemplary embodiment of the present disclosure may prevent the solder from being applied to the outer layer circuit pattern 170 and the surface treating layer 190 when the solder for a later mounting of the electronic component (not shown) is applied on the outer layer circuit pattern 170 and the surface treating layer 190. In addition, the protection layer 180 may prevent the outer layer circuit layer pattern 170 from being oxidized and corroded.

The protection layer 180 according to an exemplary embodiment of the present disclosure is formed so as to expose a portion of the outer layer circuit pattern 170. In this case, the outer layer circuit pattern 170 exposed by the protection layer 180 may be the mounting pattern which is electrically connected to the external configuration unit such as the electronic component.

In addition, according to an exemplary embodiment of the present disclosure, the protection layer 180 is formed below the first insulating layer 131 to expose the metal layer 520. In this case, the metal layer 520 exposed by the protection layer 180 may be a region which is electrically connected to the external configuration unit.

According to an exemplary embodiment of the present disclosure, the protection layer 180 is made of a thermal resistance coating material. For example, the protection layer 180 may be made of solder resist.

According to an exemplary embodiment of the present disclosure, the protection layer 180 may change a region in which the protection layer 180 is formed, according to the selection of those skilled in the art, and may also be omitted.

According to an exemplary embodiment of the present disclosure, a surface treating layer 190 is formed on the outer layer circuit pattern 170 exposed by the protection layer 180. In addition, the surface treating layer 190 is formed on the metal layer 520 exposed by the protection layer 180. The surface treating layer 190 is formed to prevent the outer layer circuit pattern 170 and the metal layer 520 exposed by the protection layer 180 from being corroded and oxidized. For example, as the surface treating layer 190, any surface treating layer known in the field of circuit board such as being plated with nickel, tin, gold, palladium, or the like, or being coated with an organic solder ability preservative (OSP) may be used.

The surface treating surface according to an exemplary embodiment of the present disclosure may be omitted according to the selection of those skilled in the art.

In addition, although not shown in FIG. 1, an external connection terminal (not shown) may be formed below the printed circuit board 100. The external connection terminal may be made of a solder material.

In addition, although the case in which the connection pad 110 has the thickness similar to the depth of the cavity 121, and the first via 140 electrically connects the connection pad 110 and the inner layer circuit pattern 150 has been described by way of example, in the exemplary embodiment of the present disclosure, the present disclosure is not limited thereto. For example, if the connection pad 110 according to an exemplary embodiment of the present disclosure has the thickness penetrating through the first insulating layer 131, the connection pad 110 is directly bonded to the inner layer circuit pattern 150, but the first via 140 may be omitted.

The printed circuit board 100 according to an exemplary embodiment of the present disclosure includes the cavity 121 having the electronic component of the lower printed circuit board disposed therein and the connection pad 110 allowing an interval between the printed circuit board 100 and the lower package to be narrowed. Therefore, when the package on package is formed later, an overall thickness of the package on package may be decreased by the printed circuit board 100 according to an exemplary embodiment of the present disclosure. A description of the package on package to which the printed circuit board 100 according to an exemplary embodiment of the present disclosure is applied will be described below with reference to FIG. 17.

Conventionally, the cavity is formed in the upper surface of the board, and the electronic components accommodated in the cavity and the board are electrically connected directly to each other. Therefore, the protection layer and the solder need to be formed in the cavity. However, there are difficulties that the upper surface of the board has a step structure due to the cavity, the forming of the protection layer and the solder on the upper surface of the board as well as in the cavity makes the process complex, and the like.

The printed circuit board 100 according to an exemplary embodiment of the present disclosure is not directly and electrically connected to the electronic component accommodated in the cavity 121. Here, the term “directly and electrically connected” means that the electronic component 121 is electrically connected to the circuit pattern of the printed circuit board 100 in the cavity 121 by the solder (e.g., the external connection terminal). Therefore, the printed circuit board 100 does not have the protection layer 180 and the solder formed in the cavity 121.

FIGS. 2 through 16 are diagrams illustrating a method for manufacturing a printed circuit board according to an exemplary embodiment of the present disclosure.

Referring to FIG. 2, a carrier substrate 500 is provided.

The carrier substrate 500 according to an exemplary embodiment of the present disclosure supports an insulating layer and a circuit layer when the insulating layer and the circuit layer for the printed circuit board are formed.

According to an exemplary embodiment of the present disclosure, the carrier substrate 500 has a structure in which a metal layer 520 is stacked on a carrier core 510.

For example, the carrier core 510 is made of an insulating material. However, the material of the carrier core 510 is not limited to the insulating material. For example, the carrier core 510 may be made of a metal material or may have a structure in which one or more insulating layers and metal layers are stacked.

For example, the metal layer 520 is made of copper (Cu). However, the material of the metal layer 520 is not limited to copper and any material may be applied without limitation as long as it is a conductive material used in the field of circuit board.

Although the carrier substrate 500 has been shown and described as a structure in which one metal layer 520 is stacked on both sides of the carrier core 510 in the exemplary embodiment of the present disclosure, the structure of the carrier substrate 500 is not limited thereto. That is, the carrier substrate 500 is schematically shown for convenience of description and understanding in the exemplary embodiment of the present disclosure. For example, the carrier substrate 500 may have a structure in which multiple metal layers are stacked on the carrier core and a release layer is formed between the multiple metal layers. Therefore, the carrier substrate except for the metal layer formed on an outermost layer may be separated and removed from the printed circuit board while the release layer is separated later. As such, the structure of the carrier substrate 500 is not limited to the structure shown and described in the exemplary embodiment of the present disclosure. That is, the carrier substrate having any structure used in the art may also be applied to the present exemplary embodiment.

Referring to FIG. 3, a plating resist 530 is formed on the carrier substrate 500.

According to an exemplary embodiment of the present disclosure, the plating resist 530 is formed on the metal layer 520 of the carrier substrate 500. In addition, the plating resist 530 according to an exemplary embodiment of the present disclosure has an opening part 531 exposing the metal layer 520 of a region in which a connection pad (not shown) and a cavity pattern (not shown) are to be formed. Here, the region in which the cavity pattern is to be formed has a size so as to mount the electronic component.

Referring to FIG. 4, the connection pad 110 and the cavity pattern 120 are formed on the carrier substrate 500.

According to an exemplary embodiment of the present disclosure, the connection pad 110 and the cavity pattern 120 are formed on the metal layer 520.

According to an exemplary embodiment of the present disclosure, the connection pad 110 and the cavity pattern 120 are formed by performing an electroplating on the opening part 531 of the plating resist 530. In this case, the metal layer 520 exposed through the opening part 531 of the plating resist 530 may serve as a seed layer for the electroplating.

The connection pad 110 according to an exemplary embodiment of the present disclosure is a circuit pattern which is electrically connected to an external configuration unit.

In addition, the cavity pattern 120 is formed to secure a space in which the electronic component mounted on the lower printed circuit board is positioned, when the package on package is formed. Therefore, the cavity pattern 120 has a size to position the electronic component in the cavity (not shown) later.

According to an exemplary embodiment of the present disclosure, since the connection pad 110 is formed in the same process as the cavity pattern 120, the connection pad 110 and the cavity pattern 120 have the same thickness. Here, the term “the same” means a term “substantially same” That is, the term “the same” means a term “the same” considering error or deviation occurring during a manufacturing process. However, the connection pad 110 is not necessarily formed to have the same thickness as the cavity pattern 120. Depending on a selection of those skilled in the art, the connection pad 110 may be thicker or thinner than the cavity pattern 120.

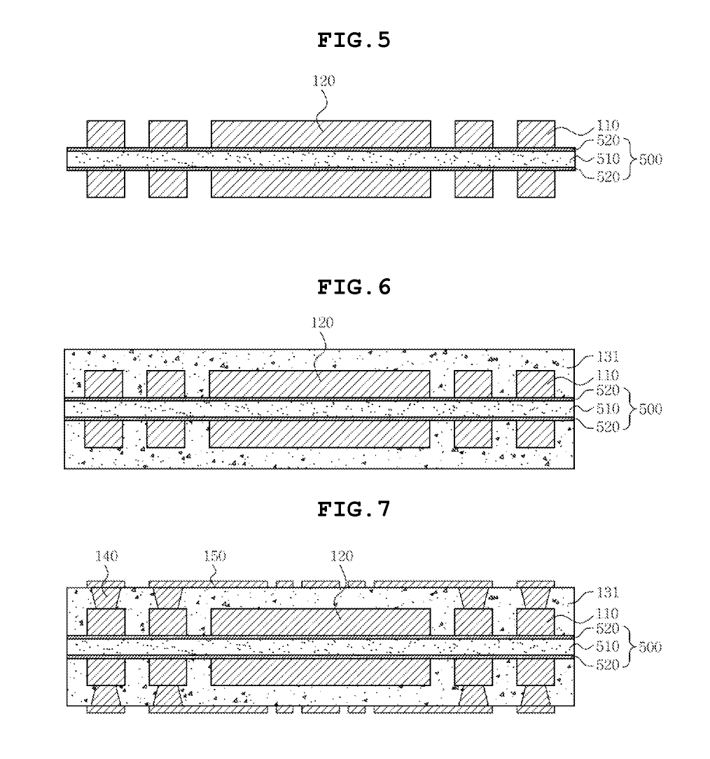

Referring to FIG. 5, the plating resist (530 in FIG. 4) is removed.

Referring to FIG. 6, the first insulating layer 131 is formed.

According to an exemplary embodiment of the present disclosure, the first insulating layer 131 is formed on the metal layer 520 to cover the connection pad 110 and the cavity pattern 120. According to an exemplary embodiment of the present disclosure, an upper surface of the first insulating layer 131 is higher than an upper surface of the connection pad 110 and an upper surface of the cavity pattern 120. That is, the first insulating layer 131 has a thickness greater than the cavity pattern 120.

According to an exemplary embodiment of the present disclosure, the first insulating layer 131 may be formed such that the first insulating layer 131 is stacked on the metal layer 520, the connection pad 110, and the cavity pattern 120 in a film form, and is then pressurized. The first insulating layer 131 according to an exemplary embodiment of the present disclosure may be formed by any method of forming the insulating layer in the field of circuit board as well as the above-mentioned method.

The first insulating layer 131 according to an exemplary embodiment of the present disclosure may be formed of a complex polymer resin which is typically used as an interlayer insulating material. For example, the first insulating layer 131 may be formed of a prepreg, Ajinomoto Build up Film (ABF), and an epoxy based resin such as FR-4, BismaleimideTriazine (BT), or the like. However, in an exemplary embodiment of the present disclosure, the material of forming the first insulating layers 131 is not limited thereto. The material of forming the insulating layer 131 according to an exemplary embodiment of the present disclosure may be selected from insulating materials known in the field of circuit board.

Referring to FIG. 7, the inner layer circuit pattern 150 and the first via 140 are formed.

According to an exemplary embodiment of the present disclosure, the inner layer circuit pattern 150 is formed on the first insulating layer 131, and the first via 140 is formed in the first insulating layer 131.

The first via 140 according to an exemplary embodiment of the present disclosure is formed in the first insulating layer 131 formed on the connection pad 110. That is, the first via 140 penetrates through the first insulating layer 131 formed on the connection pad 110 and is formed such that an upper surface of the first via 140 is bonded to the inner layer circuit pattern 150 and a lower surface of the first via 140 is bonded to the connection pad 110. The inner layer circuit pattern 150 and the connection pad 110 are electrically connected by the first via 140 formed as described above. In addition, the first via 140 is formed such that the upper surface thereof has a diameter larger than that of the lower surface thereof.

The inner layer circuit pattern 150 and the first via 140 according to an exemplary embodiment of the present disclosure may be formed by machining a via hole (not shown), forming a patterned plating resist (not shown), and then performing the plating. Alternatively, the inner layer circuit pattern 150 and the first via 140 according to an exemplary embodiment of the present disclosure may be formed by machining the via hole, performing the plating, and then forming an etching resist to perform an etching process. The above-mentioned method an exemplary method for forming the inner layer circuit pattern 150 and the first via 140, and the inner layer circuit pattern 150 and the first via 140 may be formed by any method known in the field of circuit board.

In addition, the inner layer circuit pattern 150 and the first via 140 according to an exemplary embodiment of the present disclosure may be made of any conductive material used in the field of circuit board. For example, the inner layer circuit pattern 150 and the first via 140 are made of copper (Cu).

Although the exemplary embodiment of the present disclosure describes the case in which the inner layer circuit pattern 150 is formed in a single layer, the present disclosure is not limited to the above-mentioned structure. That is, the inner layer circuit pattern 150 according to an exemplary embodiment of the present disclosure may be formed in a multi-layer according to a selection of those skilled in the art. In this case, the first insulating layer 131 may also be formed in the multi-layer, and a via connecting the inner layer circuit patterns 150 in the respective layers to each other may be further formed.

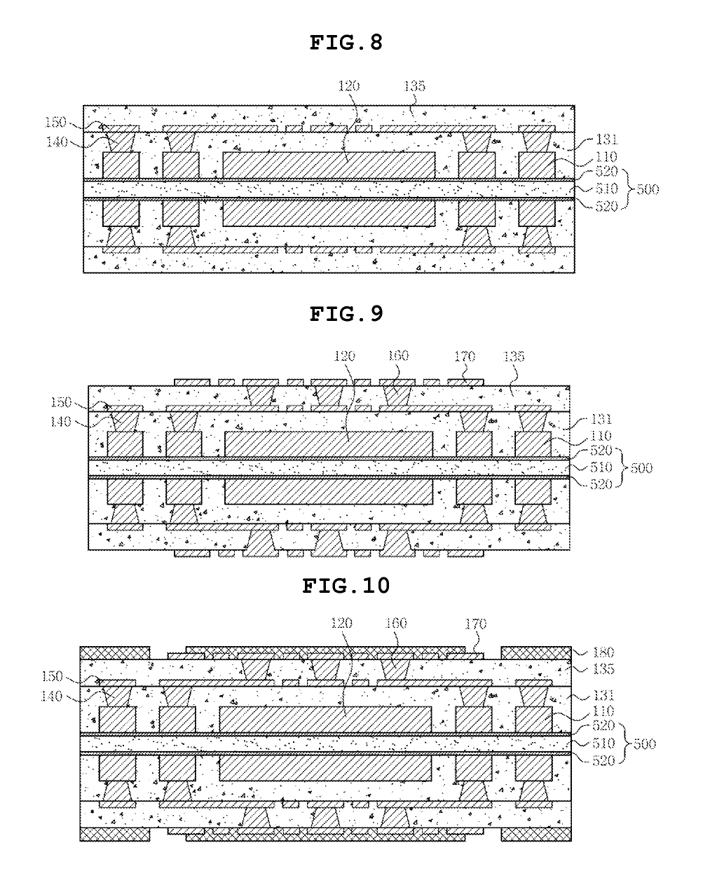

Referring to FIG. 8, the second insulating layer 135 is formed.

According to an exemplary embodiment of the present disclosure, the second insulating layer 135 is formed on the first insulating layer 131 to cover the inner layer circuit pattern 150.

According to an exemplary embodiment of the present disclosure, the second insulating layer 135 may be formed by a method in which the second insulating layer 135 is stacked on the first insulating layer 131 and the inner layer circuit pattern 150 in a film form, and is then pressurized. The second insulating layer 135 according to an exemplary embodiment of the present disclosure may be formed by any method of forming the insulating layer in the field of circuit board as well as the above-mentioned method.

According to an exemplary embodiment of the present disclosure, the second insulating layer 135 may be formed of an insulating material which does not include glass fiber, among interlayer insulating materials which are typically used. However, the material of the second insulating layer 135 is not limited thereto. That is, the second insulating layer 135 according to an exemplary embodiment of the present disclosure may be made of any material among typical interlayer insulating materials which are used in the field of circuit board and may be formed of the same material as the first insulating layer 131.

Referring to FIG. 9, the outer layer circuit pattern 170 and the second via 160 are formed.

According to an exemplary embodiment of the present disclosure, the outer layer circuit pattern 170 is formed on the second insulating layer 135, and the second via 160 is formed in the second insulating layer 135.

The outer layer circuit pattern 170 according to an exemplary embodiment of the present disclosure is a circuit pattern on the outermost layer of the printed circuit board 100. Therefore, some patterns of the outer layer circuit pattern 170 may be electrically connected to the external configuration unit such as an electronic component, a package, a substrate, or the like. Here, some patterns may be the mounting pattern which is electrically connected to the electronic component mounted on the second insulating layer 135.

The second via 160 according to an exemplary embodiment of the present disclosure penetrates through the second insulating layer 135 and is formed such that an upper portion thereof is bonded to the outer layer circuit pattern 170 and a lower portion thereof is bonded to the inner layer circuit pattern 150. The inner layer circuit pattern 150 and the outer layer circuit pattern 170 are electrically connected by the second via 160 formed as described above.

A method and material of forming the outer layer circuit pattern 170 and the second via 160 according to an exemplary embodiment of the present disclosure makes reference to the method and material of forming the inner layer circuit pattern 150 and the first via 140 of FIG. 7.

Referring to FIG. 10, the protection layer 180 is formed.

According to an exemplary embodiment of the present disclosure, the protection layer 180 is formed on the second insulating layer 135 and the outer layer circuit pattern 170. The protection layer 180 according to an exemplary embodiment of the present disclosure may prevent the solder from being applied to the outer layer circuit pattern 170 and the surface treating layer 190 when the solder for a later mounting of the electronic component (not shown) is applied on the outer layer circuit pattern 170 and the surface treating layer 190. In addition, the protection layer 180 may prevent the outer layer circuit layer from being oxidized and corroded

The protection layer 180 according to an exemplary embodiment of the present disclosure is formed so as to expose a portion of the outer layer circuit pattern 170. In this case, the outer layer circuit pattern 170 exposed by the protection layer 180 may be the mounting pattern which is electrically connected to the external configuration unit such as the electronic component.

According to an exemplary embodiment of the present disclosure, the protection layer 180 is made of a thermal resistance coating material. For example, the protection layer 180 may be made of solder resist.

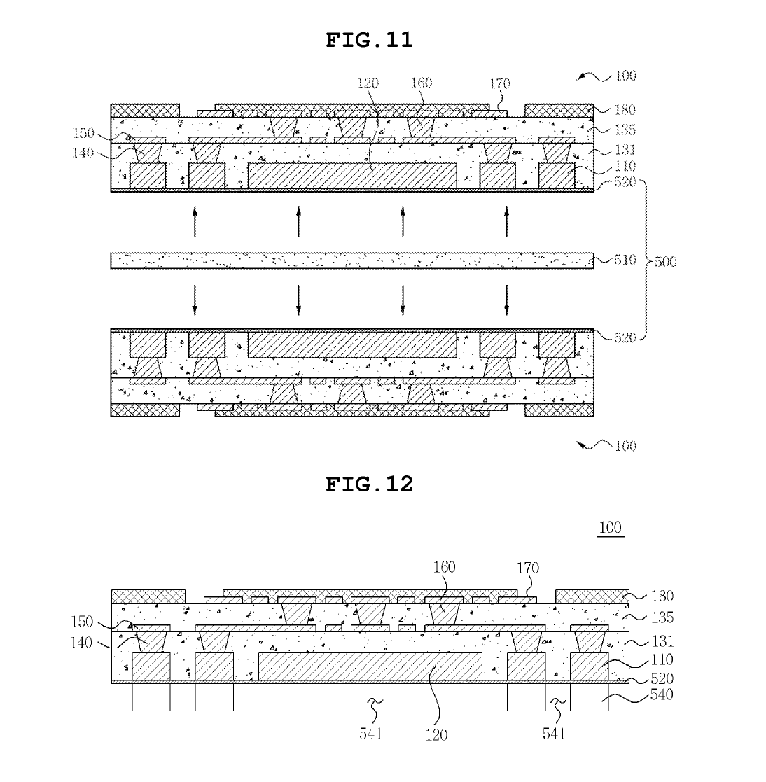

Referring to FIG. 11, the carrier substrate 500 is removed.

According to an exemplary embodiment of the present disclosure, after the carrier core 510 and the metal layer 520 are separated from each other, the carrier core 510 is removed. When the carrier core 510 is removed, printed circuit boards 100 formed on both sides of the carrier substrate 500 are separated.

Referring to FIG. 12, the etching resist 540 is formed.

The etching resist 540 according to an exemplary embodiment of the present disclosure is formed to prevent the connection pad 110 from being damaged, when the cavity pattern 120 is etched later. Therefore, the etching resist 540 is formed below the connection pad 110 in order to protect the connection pad 110 from an etching process. In this case, the etching resist 540 also simultaneously protects a portion of the metal layer 520 which is positioned in a region in which the connection pad 110 is formed.

The etching resist 540 according to an exemplary embodiment of the present disclosure is provided with an opening part 541 to expose a region except for a region in which the connection pad 110 is formed.

In addition, if the etching process which is performed later uses an etchant, the etching resist 540 according to an exemplary embodiment of the present disclosure needs to be formed of a material which does not react with the corresponding etchant.

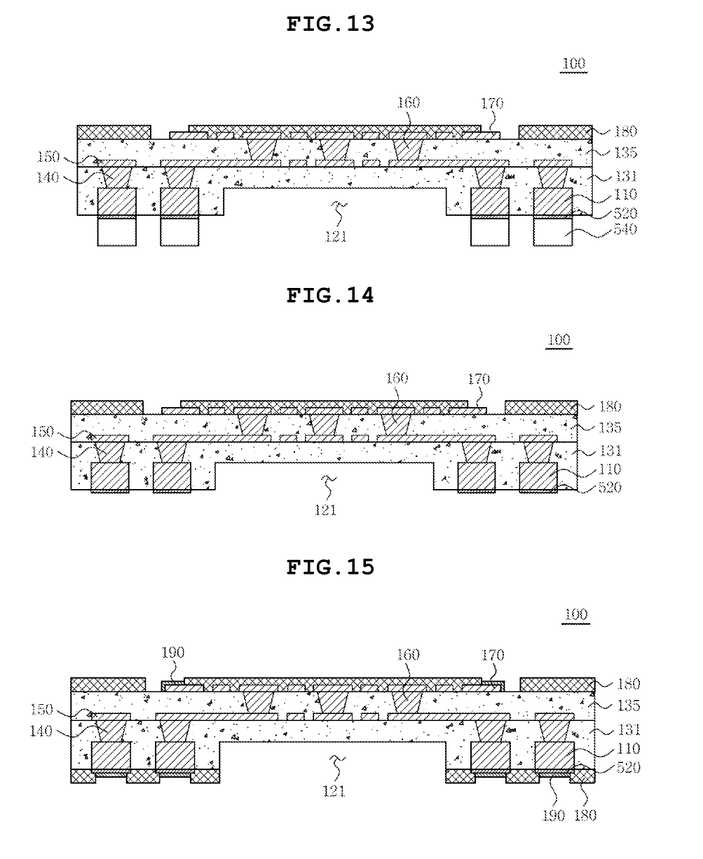

Referring to FIG. 13, the cavity 121 is formed.

According to an exemplary embodiment of the present disclosure, the etching process is performed. The metal layer 520 and the cavity pattern 120 of the region exposed by the opening part 541 of the etching resist 540 are removed by the etching process.

According to an exemplary embodiment of the present disclosure, the etching process may be performed with an etchant which reacts with the cavity pattern (120 in FIG. 12) and the metal layer 520. In this case, the etching resist 540 needs not to react with the used etchant.

According to an exemplary embodiment of the present disclosure, the cavity pattern (120 in FIG. 12) is removed by the etching process to form the cavity 121. When a package on package is formed, at least a portion of an electronic component (not shown) of a lower package is accommodated in the cavity 121 according to an exemplary embodiment of the present disclosure. According to an exemplary embodiment of the present disclosure, since the cavity 121 is formed by removing the cavity pattern (120 in FIG. 12) formed on the first insulating layer 131, an entire internal surface of the cavity 121 is all made of an insulating material. That is, it may be said that the internal surface of the cavity 121 is made of the first insulating layer 131.

According to an exemplary embodiment of the present disclosure, when the etching process is performed, the metal layer 520 positioned between the connection pad 110 and the etching resist 540 is not etched and is protected by the etching resist 540.

As a method for forming the cavity 121, there is a method in which an insulating film is stacked and a cavity portion is then removed with laser, but according to this method, processing costs are expensive and a laser sputter layer capable of stopping a propagation of laser upon a laser processing is separately required. As another method, there is a method in which a portion of the insulating film in which the cavity is to be formed is cut in advance and is then stacked, but according to this method, a side surface which is cut in advance flows down due to high temperature upon a process of forming the insulating layer, which causes a wall surface of the cavity to be non-uniform. However, according to the present disclosure, since the cavity 121 is formed by etching the cavity pattern 120 as described above, the processing costs are inexpensive and the cavity 121 having a uniform wall surface may be formed.

A depth of the cavity 121 formed described above is smaller than the thickness of the first insulating layer 131.

Referring to FIG. 14, the etching resist (540 in FIG. 13) is removed.

According to an exemplary embodiment of the present disclosure, the metal layer 520 formed below the connection pad 110 is protected from the etching process by the etching resist (540 in FIG. 13). Therefore, when the etching resist (540 in FIG. 13) is removed, the protected metal layer 520 protrudes from the lower surface of the first insulating layer 131 as shown.

Referring to FIG. 15, the surface treating layer 190 may be formed.

According to an exemplary embodiment of the present disclosure, the protection layer 180 is formed below the first insulating layer 131. The protection layer 180 formed below the first insulating layer 131 is formed to expose the metal layer 520 to the outside. In this case, the metal layer 520 which is exposed to the outside is a portion which is connected to an external connection terminal (not shown) later.

The protection layer 180 formed below the first insulating layer 131 according to an exemplary embodiment of the present disclosure is not necessarily formed in the present step. The protection layer 180 may also be formed in any step among steps after the metal layer 520 is patterned. In addition, the protection layer 180 formed below the first insulating layer 131 according to an exemplary embodiment of the present disclosure may be omitted according to a selection of those skilled in the art.

According to an exemplary embodiment of the present disclosure, the surface treating layer 190 is formed on the outer layer circuit pattern 170 exposed by the protection layer 180. For example, the surface treating layer 190 is formed on the mounting pattern of the outer layer circuit pattern 170. In addition, according to an exemplary embodiment of the present disclosure, the surface treating layer 190 is formed on the metal layer 520 exposed by the protection layer 180.

The surface treating layer 190 according to an exemplary embodiment of the present disclosure prevents the outer layer circuit pattern 170 and the metal layer 520 exposed by the protection layer 180 from being corroded and oxidized. For example, the surface treating layer 190 may be formed with a surface treating method known in the field of circuit board such as being plated with nickel, tin, gold, palladium, or the like, or being coated with an organic solder ability preservative (OSP).

The step of forming the surface treating surface 190 according to an exemplary embodiment of the present disclosure may be omitted according to the selection of those skilled in the art or may be changed after the outer layer circuit pattern 179 is formed. In addition, the surface treating layer 190 according to an exemplary embodiment of the present disclosure may also be selectively formed on only a desired pattern of the outer layer circuit pattern 170 and the metal layer 520 according to the selection of those skilled in the art.

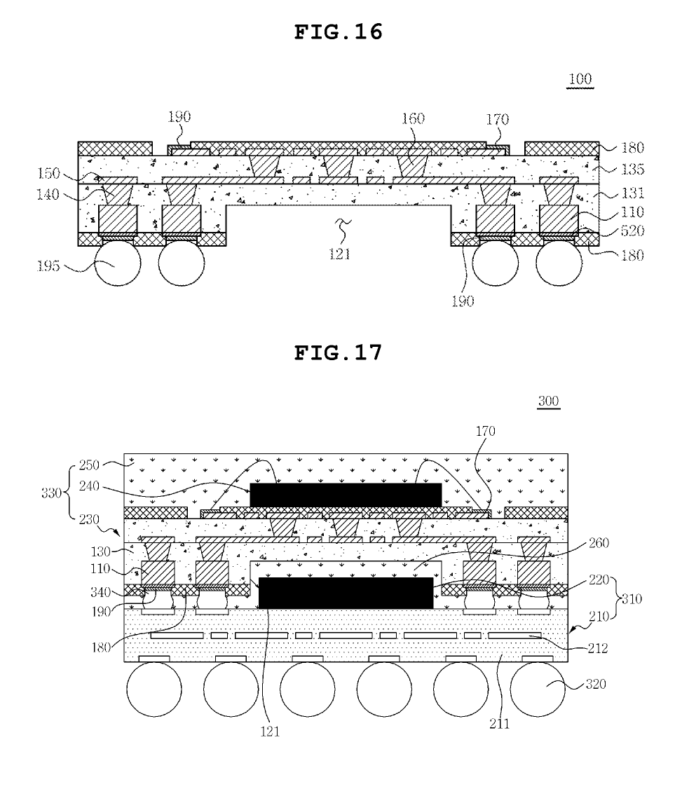

Referring to FIG. 16, the external connection terminal 195 is formed.

According to an exemplary embodiment of the present disclosure, the external connection terminal 195 is formed on a lower surface of the surface treating layer exposed to the outside by the protection layer 180 of the surface treating layer 190 formed below the metal layer 520. Alternatively, in a case in which the surface treating layer 190 and the protection layer 180 are omitted, the external connection terminal 195 is formed on a lower surface of the connection pad 110 exposed from the first insulating layer 131. The external connection terminal 195 according to an exemplary embodiment of the present disclosure electrically connects the external configuration unit such as the substrate, the package, the main board, or the like to the printed circuit board 100. For example, the external connection terminal 195 may be formed of a solder material of a ball form. However, the form of the external connection terminal 195 is not limited to the ball form.

The printed circuit board 100 manufactured according to an exemplary embodiment of the present disclosure has the cavity 121 formed therein. In addition, when the package on package is formed, the cavity 121 accommodates a portion of an electronic component (not shown) mounted on a lower package (not shown). Therefore, an interval between the printed circuit board 100 and the lower printed circuit board is further decreased as much as a thickness of the electronic component accommodated in the cavity 121. Therefore, the printed circuit board 100 and the lower package according to an exemplary embodiment of the present disclosure may be connected to each other by the external connection terminal 195 having a small size. In addition, as the size of the external connection terminal 195 is decreased, the external connection terminal 195 may be disposed at a fine interval, and an occurrence of defect due to a bridge between the external connection terminals 195 may be prevented or decreased.

The method for manufacturing a printed circuit board 100 according to an exemplary embodiment of the present disclosure is not limited to those illustrated in FIGS. 2 through 16. The methods of FIGS. 2 through 16 are merely examples, and the carrier substrate, the method of forming the circuit pattern, the etching method, and the like may be changed to any one of structures and methods known in the field of circuit board according to the selection of those skilled in the art.

FIG. 17 is an illustrative diagram illustrating a package on package according to an exemplary embodiment of the present disclosure.

Referring to FIG. 17, the package on package 300 according to an exemplary embodiment of the present disclosure has structure in which an upper package 330 is stacked on a lower package 310.

According to an exemplary embodiment of the present disclosure, the lower package 310 includes a lower package substrate 210 and a first electronic component 220.

The lower package substrate 210 according to an exemplary embodiment of the present disclosure includes an insulating layer 211 and a circuit pattern 212 formed on the insulating layer 211. The first electronic component 220 is disposed on the lower package substrate 210.

The first electronic component 220 according to an exemplary embodiment of the present disclosure may be any kind of electronic component which may be applied to a package field.

In addition, a first external connection terminal 320 may be formed below the lower package 310 according to an exemplary embodiment of the present disclosure. The first external connection terminal 320 according to an exemplary embodiment of the present disclosure may be formed of a solder material of a ball form.

According to an exemplary embodiment of the present disclosure, the upper package 330 includes an upper package substrate 230, a second electronic component 240, and a first molding member 250.

The upper package substrate 230 according to an exemplary embodiment of the present disclosure is the printed circuit board 100 of FIG. 1.

According to an exemplary embodiment of the present disclosure, the upper package substrate 230 is connected to one surface (upper surface) of the lower package substrate 210 on which the first electronic component 220 is mounted. The above-mentioned upper package substrate 230 includes at least one insulating layer 130. In addition, the insulating layer 130 has a cavity 121 accommodating at least a portion of the first electronic component 220, and an internal surface of the cavity 121 is made of an insulating material.

According to an exemplary embodiment of the present disclosure, the second electronic component 240 is disposed on the upper package substrate 230. In this case, the second electronic component 240 is electrically connected to the outer layer circuit pattern 170 of the upper package substrate 230 through a wire. Here, the outer layer circuit pattern 170 which is electrically connected to the second electronic component 240 by the wire is the mounting pattern. Although an exemplary embodiment of the present disclosure describes the case in which the second electronic component 240 and the upper package substrate 230 are connected to each other by the wire, the present disclosure is not limited thereto. That is, the second electronic component 240 and the upper package 330 may be electrically connected to each other through a conductive material. In addition, according to an exemplary embodiment of the present disclosure, the second electronic component 240 may be a memory device. However, a kind of second electronic component 240 is not limited to the memory device, and may be any kind of electronic component which may be used in the package field.

According to an exemplary embodiment of the present disclosure, the first molding member 250 is formed on the upper package substrate 230 to cover the second electronic component 240. The first molding member 250 according to an exemplary embodiment of the present disclosure is formed to protect the second electronic component 240 from the outside. For example, the first molding member 250 may be made of an epoxy molding compound (EMC) or silicone gel. However, the material of the first molding member 250 is not limited to the EMC and the silicone gel, and any one of the molding materials known in the known package field may be used.

In addition, according to an exemplary embodiment of the present disclosure, a second external connection terminal 340 may be formed below the upper package 330. The second external connection terminal 340 according to an exemplary embodiment of the present disclosure is the external connection terminal 195 of FIG. 16.

According to an exemplary embodiment of the present disclosure, when the upper package 330 is stacked on the lower package 310, a portion of the first electronic component 220 is accommodated in the cavity 121 of the upper package substrate 230. In this case, the cavity 121 accommodates the first electronic component 220 in a state in which the cavity 121 is spaced apart from the first electronic component 220 by a predetermined interval.

According to an exemplary embodiment of the present disclosure, a second molding member 260 may be formed between an internal surface of the cavity 121 and the first electronic component 220. That is, the second molding member 260 fills a spaced space between the cavity 121 and the first electronic component 220. For example, the second molding member 260 may be made of an epoxy molding compound (EMC). However, the material of the second molding member 260 is not limited to the EMC, and any one of the molding materials known in the known package field may be used. As shown in FIG. 17, the second molding member 260 is formed between the upper package 330 and the lower package 310 as well as between the cavity 121 and the first electronic component 220. However, if the second molding member 260 is formed between the cavity 121 and the first electronic component 220, whether or not the second molding member 260 is formed in other regions and a position at which the second molding member 260 is formed may be changed.

In addition, the cavity 121 makes the interval between the upper package 330 and the lower package 310 decreased as much as a thickness of the electronic component accommodated in the cavity 121. In addition, the connection pads 110 are formed at both sides of the cavity 121 to electrically connect an inner portion of the upper package 330 to the second external connection terminal 340. Therefore, even though the second external connection terminal 340 is formed by a solder having a small size, the second external connection terminal 340 may sufficiently connect the upper package 330 and the lower package 310 to each other. As such, since the second external connection terminal 340 is formed by the solder having the small size, a plurality of second external connection terminals 340 may be disposed at a fine interval. In addition, an occurrence of defect due to the bridge between the second external connection terminals 340 may be prevented or decreased. In addition, since the second external connection terminal 340 having the small size is used, a thickness of the package on package 300 may also be decreased.

In addition, according to the related art, the cavity for the mounting of the electronic component is formed in the lower package substrate. In the case in which the cavity is formed in the lower package substrate according to the related art, an area in which a circuit may be formed is reduced as much as an area in which the cavity is formed. In addition, the protection layer and the solder (external connection terminal) such as the solder resist need to be formed in the cavity for an electrical connection with the electronic component. However, since the upper surface of the substrate has s step structure due to the cavity, it is difficult to form the protection layer and the solder.

However, the printed circuit board (100 in FIG. 1) according to an exemplary embodiment of the present disclosure is applied to the upper package 330 of the package on package 300. That is, the cavity 121 which accommodates the electronic component is formed in the lower surface of the upper package substrate 230. In addition, the accommodated electronic component is not directly and electrically connected to the upper package substrate 230 in the cavity 121. Therefore, the protection layer and the solder need not to be formed in the cavity 121.

Although the embodiments of the present disclosure have been disclosed for illustrative purposes, it will be appreciated that the present disclosure is not limited thereto, and those skilled in the art will appreciate that various modifications, additions and substitutions are possible, without departing from the scope and spirit of the disclosure.

Accordingly, any and all modifications, variations or equivalent arrangements should be considered to be within the scope of the disclosure, and the detailed scope of the disclosure will be disclosed by the accompanying claims.

What is claimed is:

1. A printed circuit board connected to one surface of a substrate having a first electronic component mounted on the one surface and including at least one insulating layer, wherein
the at least one insulating layer has a cavity accommodating at least a portion of the first electronic component formed therein, and
the cavity has an internal surface made of an insulating material.

2. The printed circuit board of claim 1, wherein the cavity has a depth smaller than a thickness of the insulating layer.

3. The printed circuit board of claim 1, further comprising a mounting pattern formed on the insulating layer and electrically connected to a second electronic component mounted on the insulating layer.

4. The printed circuit board of claim 1, further comprising a connection pad at least a portion of which is buried in the insulating layer.

5. The printed circuit board of claim 4, wherein the connection pad surrounds a side edge of the cavity.

6. The printed circuit board of claim 4, wherein the connection pad has a thickness equal to a depth of the cavity.

7. The printed circuit board of claim 4, further comprising a via formed in the insulating layer and formed on an upper surface of the connection pad.

8. The printed circuit board of claim 7, wherein the via has an upper surface having a diameter greater than that of a lower surface.

9. The printed circuit board of claim 1, wherein entirety of the internal surface of the cavity is made of the same insulating material as the insulating layer.

10. The printed circuit board of claim 4, further comprising a metal layer formed on a lower surface of the connection pad.

11. The printed circuit board of claim 7, further comprising an inner layer circuit pattern formed on the insulating layer and bonded to an upper surface of the via.

12. The printed circuit board of claim 1, wherein the cavity accommodates the first electronic component and the cavity is spaced apart from the first electronic component by a predetermined interval.

13. A method for manufacturing a printed circuit board, the method comprising steps of:
forming a cavity pattern on a carrier substrate;
forming an insulating layer formed on the carrier substrate to bury the cavity pattern;
removing the carrier substrate; and
removing the cavity pattern to form a cavity in the insulating layer.

14. The method of claim 13, wherein in the step of forming the cavity pattern, when the cavity pattern is formed, a connection pad is further formed on the carrier substrate.

15. The method of claim 14, wherein in the step of forming the insulating layer, the insulating layer is formed to bury the cavity pattern and the connection pad.

16. The method of claim 14, wherein the carrier substrate includes a metal layer on or on and below a carrier core.

17. The method of claim 16, wherein the step of removing the carrier substrate includes:
removing the carrier core by separating the carrier core and the metal layer from each other;
forming an etching resist formed at a position corresponding to the connection pad below the metal layer; and
removing the metal layer exposed to the outside by the etching resist.

18. The method of claim 13, wherein in the step of forming the cavity pattern, the cavity pattern is formed in an electroplating scheme.

19. The method of claim 15, further comprising, after the step of forming the insulating layer, forming a via in an upper surface of the connection pad and penetrating through the insulating layer.

20. The method of claim 19, further comprising, during or after the step of forming the via, forming an inner layer circuit pattern on the insulating layer and bonded to an upper surface of the via.

21. A package on package comprising:
a lower package including a lower package substrate and a first electronic component disposed on the lower package substrate;
an upper package substrate including at least one insulating layer, the insulating layer having a cavity accommodating at least a portion of the first electronic component formed therein, and the cavity having an internal surface made of an insulating material; and
an external connection terminal formed between the lower package substrate and the upper package substrate and electrically connecting the upper package substrate and the lower package substrate,
wherein the cavity accommodates at least a portion of the first electronic component.

22. The package on package of claim 21, wherein the internal surface of the cavity in the upper package substrate is made of the same insulating material as the insulating layer.

23. The package on package of claim 21, wherein the upper package substrate further includes a metal layer formed below the upper package substrate, the metal layer contacting the external connection terminal.

24. The package on package of claim 21, wherein the upper package substrate further includes an inner layer circuit pattern formed therein.

25. The package on package of claim 21, further comprising a second electronic component mounted on the upper package substrate.

26. The package on package of claim 25, wherein the second electronic component is electrically connected to the upper package substrate by a wire bonding.

27. The package on package of claim 25, further comprising a first molding member formed on the upper package substrate and covering the second electronic component.

28. The package on package of claim 21, wherein the cavity extends from a lower surface of the upper package substrate to a middle of the upper package substrate in a concave shape.

29. The package on package of claim 21, wherein the cavity accommodates the first electronic component such that the cavity is spaced apart from the first electronic component by a predetermined interval.

30. The package on package of claim 21, wherein a second molding member is further formed between the internal surface of the cavity and the first electronic component.

31. A printed circuit board connected to a substrate on which a first electronic component is mounted, the printed circuit board including:
a first insulating layer having a cavity accommodating at least a portion of the first electronic component; and
an inner layer circuit pattern on a first surface of the insulating layer opposite to a second surface of the insulating layer where the cavity is disposed.

32. The printed circuit board of claim 31, further comprising:
a connection pad extending from the second surface of the insulating layer to inside of the insulating layer; and
a first via extending from the first surface of the insulating layer to the connection pad,
wherein the via is filled with a conducting material and the inner layer circuit pattern is disposed on the via and the first surfaced of the insulating layer.

33. The printed circuit board of claim 32, further comprising:
a metal layer disposed on the connection pad;
a first surface treating layer disposed on the metal layer; and
a first protection layer disposed on the first insulating layer to expose the cavity and the first surface treating layer.

34. The printed circuit board of claim 32, further comprising:
a second insulating layer disposed on first surface of the first insulating layer and burying the inner layer circuit pattern;
a second via extending from the inner layer circuit pattern to a surface of the second insulating layer, the second via filled with a conducting material;
an outer layer circuit pattern disposed on the second via and the surface of the second insulating layer;
a surface treating layer covering a portion of the outer layer circuit pattern; and
a second protection layer disposed on the outer layer circuit pattern and the surface of the second insulating layer.

35. The printed circuit board of claim 32, wherein the connection pad has a thickness equal to a depth of the cavity.

36. The printed circuit board of claim 32, wherein the diameter of the via increases in a direction toward the first surface of the first insulating layer.

37. The printed circuit board of claim 31, wherein entirety of the internal surface of the cavity is made of the same insulating material as the insulating layer.

38. The printed circuit board of claim 31, wherein the cavity is spaced apart from the first electronic component by a predetermined interval.
